(19) United States
(12) Patent Application Publication
(10) Pub. No.: US 2026/0137012 A1
(43) Pub. Date: May 14, 2026

(54) DIE STACK ON COPPER CLIP AND DOUBLE-SIDED COOLING

(71) Applicant: Qorvo US, Inc., Greensboro, NC (US)

(72) Inventor: MD Hasnine, Wylie, TX (US)

(21) Appl. No.: 19/320,341

(22) Filed: Sep. 5, 2025

Related U.S. Application Data
(60) Provisional application No. 63/719,915, filed on Nov. 13, 2024.

(51) Int. Cl. H01L 23/495; H01L 23/00; H01L 23/31; H01L 23/373

(52) U.S. Cl. CPC H10W 90/811; H10W 40/258; H10W 74/111; H10W 72/073; H10W 72/076; H10W 72/352; H10W 72/652; H10W 72/886; H10W 90/736; H10W 90/756; H10W 90/766

(57) ABSTRACT

Aspects of the disclosure provide a semiconductor package and one or more methods of producing the same. The disclosed semiconductor package includes a lead-frame substrate; a first die attached to a first side of the substrate via a first layer of a coefficient of thermal expansion (CTE)-matched copper paste at a first location on the first side of the substrate; a first set of copper clips attached to the first die and a second location on the first side of the substrate via a second layer of CTE-matched copper paste; a second die attached to the first die via a third layer of CTE-matched copper paste; and a second set of copper clips attached to the second die and a third location on the first side of the substrate via a fourth layer of CTE-matched copper paste. In various embodiments, a wireless device includes the disclosed semiconductor package.

### CROSS-REFERENCE TO RELATED APPLICATION

This application claims priority to U.S. Patent Application No. 63/719,915, filed Nov. 13, 2024, all of which is incorporated by reference herein in its entirety.

### TECHNICAL FIELD

The present disclosure relates generally to semiconductor cooling methodologies, and in particular, relates to semiconductor packages and methods for making a wire bonded semiconductor package with double-sided cooling.

### BACKGROUND

Advanced semiconductor electronics are typically assembled using cutting-edge packaging techniques. As known in the industry, semiconductor packaging using 3D (three-dimensional) stacking can offer seamless integration of various sensitive components in a compact space. While rapid advances in 3D packaging processes necessitate the development of intricate systems in electronic designs within a smaller footprint, they can nevertheless lead to more pronounced thermal issues from resulting high temperatures due to the enormous heat generated by the densely stacked dies. This is particularly apparent when gate spacing is reduced in devices, such as, for example, high-power radio frequency (RF) GaN/GaAs devices, which often result in intensified heat concentration that causes device heating and elevated junction temperatures. This uncontrolled elevation may detrimentally affect both performance and reliability such high-power devices. Indeed, the heat generated from these devices is quite intense that conventional heat sinks prove to be insufficient in dispersing such concentrated heat flux.

Additionally, wide band gap semiconductors, such as, silicon carbide (SiC) and gallium nitride (GaN) generate substantial heat during high power or high voltage applications, which must be effectively dissipated to ensure optimal performance and longevity. Currently, power modules use copper-based lead frames to attach the die with solder or sintering materials and these power modules dissipate heat through the copper-based lead frame to the customer's printed circuit board (PCB). However, this method is inefficient and does not meet the heat dissipation demands of both current and future applications. Heat sinks alone are also inadequate for managing the concentrated heat flux in these devices, particularly as gate spacing decreases. This inefficiency results in high thermal resistance, which can degrade the device's lifespan. Therefore, both top-side and bottom-side cooling are necessary to establish an enhanced thermal pathway to the ambient environment for high-power modules.

Furthermore, the significant difference in the coefficient of thermal expansion (CTE) between GaN/SiC dies and Cu substrates can lead to mechanical stress and stress-induced failures, such as cracking and delamination. This CTE-induced stress can result in mechanical field failures and increase the thermal resistance of the device, ultimately degrading its lifetime. Therefore, an alternative die stacking package design, assembly, and cooling solution are necessary to enhance the thermomechanical reliability of high-power/high-voltage modules based on wide band gap semiconductor devices. As such, thermal management emerges as a critical concern in 3D RF GaN/GaAs integration. Consequently, there is a demand for advanced thermal solutions tailored for wide bandgap semiconductors based on materials, such as GaN, SiC, and GaAs, to facilitate their wide adoption and extensive utilization in high-power high-voltage applications.

### SUMMARY

Embodiments of the present disclosure include advanced semiconductor packaging techniques with innovative cooling capabilities designed for wide band gap semiconductor packages. Aspects of the disclosure advantageously provide a semiconductor package and one or more methods of making a semiconductor package with double-sided cooling.

In an exemplary aspect, a semiconductor package is provided. The semiconductor package includes a lead-frame substrate; a first die attached to a first side of the lead-frame substrate via a first layer of a coefficient of thermal expansion (CTE)-matched copper paste at a first location on the first side of the lead-frame substrate; a first set of copper clips attached to the first die and a second location on the first side of the lead-frame substrate via a second layer of CTE-matched copper paste; a second die attached to the first die via a third layer of CTE-matched copper paste; and a second set of copper clips attached to the second die and a third location on the first side of the lead-frame substrate via a fourth layer of CTE-matched copper paste.

In one or more embodiments, the semiconductor package further includes a fifth layer of CTE-matched copper paste disposed atop the second die and in-between the second set of copper clips, wherein the fifth layer of CTE-matched copper paste and the second set of copper clips are ground to form a smooth surface; and a gold/nickel metallization layer disposed atop the smooth surface. In one or more embodiments, the fifth layer of CTE-matched copper paste is a slab of CTE-matched copper paste that functions as a heat spreader. In one or more embodiments, the third layer of CTE-matched copper paste is a slab of CTE-matched copper paste that functions as a heat spreader.

In one or more embodiments, the semiconductor package further includes a third die disposed atop one copper clip of the first set of copper clips; and a wire bond formed between a top surface of the third die and a fourth location on the first side of the lead-frame substrate.

In one or more embodiments, the semiconductor package further includes one or more drops of cured CTE-matched copper paste disposed in gap areas between copper clips of the first set of copper clips and between copper clips of the second set of copper clips.

In one or more embodiments, the semiconductor package further includes a mold compound that surrounds and encapsulates the lead-frame substrate, the first die, the second die, the first set of copper clips, and the second set of copper clips.

In one or more embodiments, the semiconductor package further includes a gold/nickel metallization layer disposed atop the mold compound. In one or more embodiments, the semiconductor package further includes a printed circuit board (PCB) attached to a second side of the lead-frame substrate via a solder paste. In one or more embodiments, a wireless device may include the semiconductor package as disclosed herein.

In an exemplary aspect, a method for forming a semiconductor package is provided. The method includes attaching a first die at a first location on a first side of a lead-frame substrate via a first layer of a coefficient of thermal expansion (CTE)-matched copper paste; attaching a first set of copper clips to the first die and a second location on the first side of the lead-frame substrate via a second layer of CTE-matched copper paste; attaching a second die to the first die via a third layer of CTE-matched copper paste; and attaching a second set of copper clips to the second die and a third location on the first side of the lead-frame substrate via a fourth layer of CTE-matched copper paste.

In one or more embodiments, the method may further include disposing a fifth layer of CTE-matched copper paste atop the second die and in-between the second set of copper clips; grinding the fifth layer of CTE-matched copper paste and the second set of copper clips to form a smooth surface; and disposing a gold/nickel metallization layer atop the smooth surface.

In one or more embodiments, the fifth layer of CTE-matched copper paste is a slab of CTE-matched copper paste that functions as a heat spreader. In one or more embodiments, the third layer of CTE-matched copper paste is a slab of CTE-matched copper paste that functions as a heat spreader.

In one or more embodiments, the method may further include disposing a third die atop one copper clip of the first set of copper clips; and forming a wire bond between a top surface of the third die and a fourth location on the first side of the lead-frame substrate.

In one or more embodiments, the method may further include disposing one or more drops of cured CTE-matched copper paste in gap areas between copper clips of the first set of copper clips and between copper clips of the second set of copper clips.

In one or more embodiments, the method may further include dispensing a mold compound that surrounds and encapsulates the lead-frame substrate, the first die, the second die, the first set of copper clips, and the second set of copper clips.

In one or more embodiments, the method may further include disposing a gold/nickel metallization layer atop the mold compound. In one or more embodiments, the method may further include attaching a printed circuit board (PCB) to a second side of the lead-frame substrate via a solder paste. In one or more embodiments, a wireless device may include the semiconductor package produced via the method as disclosed herein.

In an exemplary aspect, a wireless device is provided. The wireless device includes a semiconductor package, which includes a lead-frame substrate; a first die attached to a first side of the lead-frame substrate via a first layer of a coefficient of thermal expansion (CTE)-matched copper paste at a first location on the first side of the lead-frame substrate; a first set of copper clips attached to the first die and a second location on the first side of the lead-frame substrate via a second layer of CTE-matched copper paste; a second die attached to the first die via a third layer of CTE-matched copper paste; and a second set of copper clips attached to the second die and a third location on the first side of the lead-frame substrate via a fourth layer of CTE-matched copper paste.

Additional aspects, embodiments, implementations, features, and advantages of the present disclosure will become apparent from the following detailed description.

### BRIEF DESCRIPTION OF THE DRAWINGS

Illustrative embodiments of the present disclosure will be described with reference to the accompanying drawings, of which:

FIG. 1 illustrates a cross-sectional view of an example semiconductor package, according to aspects of the present disclosure.

FIG. 2 illustrates a cross-sectional view of an example semiconductor package, according to aspects of the present disclosure.

FIG. 3 illustrates a flowchart for a method for forming an example semiconductor package, according to aspects of the present disclosure.

FIG. 4 illustrates an electronic device or a wireless device comprising a semiconductor package, according to aspects of the present disclosure.

### DETAILED DESCRIPTION

For the purposes of promoting an understanding of the principles of the present disclosure, reference will now be made to the embodiments illustrated in the drawings, and specific language will be used to describe the same. It is nevertheless understood that no limitation to the scope of the disclosure is intended. Any alterations and further modifications to the described devices, systems, and methods, and any further application of the principles of the present disclosure are fully contemplated and included within the present disclosure as would normally occur to one skilled in the art to which the disclosure relates. In particular, it is fully contemplated that the features, components, and/or steps described with respect to one embodiment may be combined with the features, components, and/or steps described with respect to other embodiments of the present disclosure. For the sake of brevity, however, the numerous iterations of these combinations will not be described separately.

In accordance with one or more embodiments herein, advanced thermal solutions tailored for wide bandgap semiconductors/modules and packaging that enable top-side and bottom-side cooling of such high-power modules thereof are disclosed. The disclosed semiconductor packaging/modules are designed and configured for materials, such as GaN, SiC, and GaAs, to facilitate their wide adoption and extensive utilization in high-power high-voltage applications.

This disclosed packaging and methodologies for forming such semiconductor packaging includes, for example, a high-power die attached to a lead frame substrate using a coefficient of thermal expansion (CTE)-matched engineered copper paste, which enables die stacking. In accordance with one or more embodiments, the CTE-matched engineered copper paste, with a CTE in the range of 5-16 ppm, can help mitigate thermal mismatch stress between the die and the substrate, in accordance with various embodiments. In accordance with one or more embodiments, a cut-out copper clip can be attached to the die top, creating an interconnect with the gate and source using the CTE-matched copper paste. Since the copper clip does not cover the entire die area, the CTE-matched copper paste can be applied between the copper clip pads to reduce hot spot generation and facilitate the stacking of another die. Another die can be stacked on the CTE-matched copper paste, and a second copper clip can be placed on the stacked die, allowing for topside cooling of both the stacked die and the copper clip. The gap between the stacked copper clips can be filled with the CTE-matched copper paste, which can act as a heat spreader. In accordance with one or more embodiments, additional dies can be attached on top of the copper clip and connected to the gate and source using wire bonds.

In accordance with one or more embodiments, the disclosed semiconductor package and the method of forming said packages can enhance die and copper clip stacking capability while improving the module's heat-spreading performance through both top and bottom-side cooling technology. Accordingly, the disclosed packaging and assembling methods incorporate a lead frame substrate, CTE-matched engineered copper paste, and cut-out copper clips, all of which enable top-side and bottom-side cooling of high-power/high-voltage modules. In accordance with one or more embodiments, CTE-matched engineered copper paste can be printed between the Cu clips to further enhance thermal management and eliminate any hot spots.

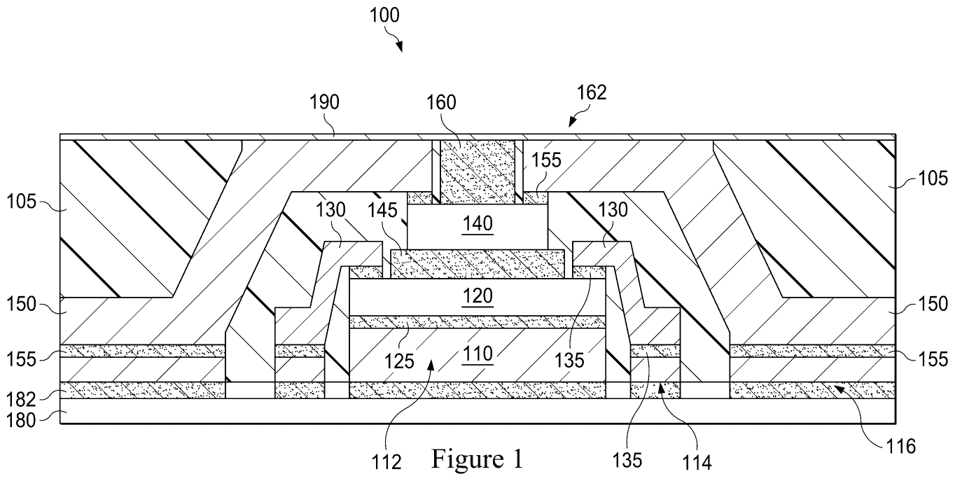

Various embodiments of the disclosure are described below in further detail with respect to the FIGS. 1, 2, 3, and 4.

FIG. 1 illustrates an example semiconductor package 100, according to aspects of the present disclosure. In one or more embodiments, the semiconductor package 100 may include a wide band gap semiconductor package with one or more dies in a stacked configuration. In some embodiments, the semiconductor package 100 may be produced or manufactured using advanced semiconductor packaging techniques as disclosed herein.

As illustrated in FIG. 1, the semiconductor package 100 includes a lead frame substrate 110 and a first die 120 attached to a first side of the lead-frame substrate 110 via a first layer of a coefficient of thermal expansion (CTE)-matched copper paste 125 at a first location 112 on the first side of the lead-frame substrate 110, as shown in FIG. 1. In one or more embodiments, the CTE of the CTE-matched copper paste 125 matches a CTE of the first die 120.

As further illustrated in FIG. 1, the semiconductor package 100 further includes a first set of copper clips 130 attached to the first die 120 and a second location 114 on the first side of the lead-frame substrate 110 via a second layer of CTE-matched copper paste 135. In one or more embodiments, each copper clip of the first set of copper clips 130 includes a proximal end and a distal end, wherein the proximal end is attached to the first die 120 and the distal end is attached to the second location 114 on the first side of the lead-frame substrate 110. In one or more embodiments, the attachment of the proximal end to the first die 120 occurs via the second layer of CTE-matched copper paste 135. In one or more embodiments, the attachment of the distal end to the second location 114 of the lead-frame substrate 110 occurs via the second layer of CTE-matched copper paste 135, as shown in FIG. 1.

As further shown in FIG. 1, the semiconductor package 100 further includes a second die 140 attached to the first die 120 via a third layer of CTE-matched copper paste 145. In one or more embodiments, the third layer of CTE-matched copper paste 145 is a slab of CTE-matched copper paste that functions as a heat spreader. In one or more embodiments, the CTE of the CTE-matched copper paste 145 matches a CTE of the second die 140 and the CTE of the first die 120.

As further illustrated in FIG. 1, the semiconductor package 100 further includes a second set of copper clips 150 attached to the second die 140 and a third location 116 on the first side of the lead-frame substrate 110 via a fourth layer of CTE-matched copper paste 155. In one or more embodiments, each copper clip of the second set of copper clips 150 includes a proximal end and a distal end, wherein the proximal end is attached to the second die 140 and the distal end is attached to the third location 116 on the first side of the lead-frame substrate 110. In one or more embodiments, the attachment of the proximal end to the second die 140 occurs via the fourth layer of CTE-matched copper paste 155. In one or more embodiments, the attachment of the distal end to the third location 116 of the lead-frame substrate 110 occurs via the fourth layer of CTE-matched copper paste 155, as shown in FIG. 1.

In one or more embodiments, the semiconductor package 100 further includes one or more drops of cured CTE-matched copper paste disposed in gap areas between copper clips of the first set of copper clips 130. In one or more embodiments, the semiconductor package 100 further includes one or more drops of cured CTE-matched copper paste disposed in gap areas between copper clips of the second set of copper clips 150.

In one or more embodiments, the semiconductor package 100 further includes a mold compound 105 that surrounds and encapsulates the lead-frame substrate 110, the first die 120, the second die 140, the first set of copper clips 130, and the second set of copper clips 150.

In one or more embodiments, the semiconductor package 100 further includes a fifth layer of CTE-matched copper paste 160 disposed atop the second die 140 and in-between the second set of copper clips 150, as shown in FIG. 1. In one or more embodiments, the fifth layer of CTE-matched copper paste 160 is a slab of CTE-matched copper paste that functions as a heat spreader. In one or more embodiments, the fifth layer of CTE-matched copper paste 160 and the second set of copper clips 150 are ground to form a smooth surface 162, as shown in FIG. 1.

In one or more embodiments, the semiconductor package 100 further includes a gold/nickel metallization layer 190 disposed atop the mold compound 105, as shown in FIG. 1. In one or more embodiments, the semiconductor package 100 further includes a printed circuit board (PCB) 180 attached to a second side of the lead-frame substrate 110 via a solder paste 182, for example, in a ball grid array (BGA) or a land grid array (LGA).

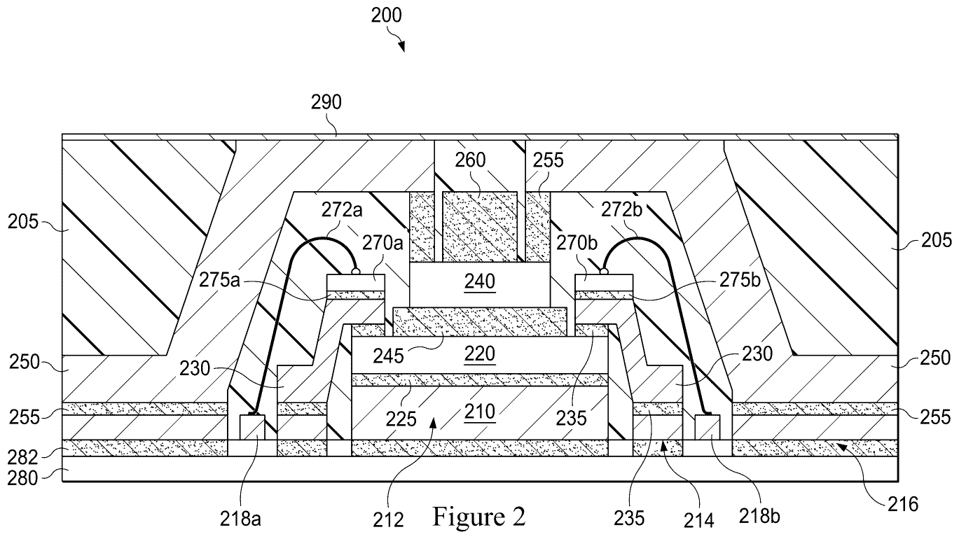

FIG. 2 illustrates an example semiconductor package 200, according to aspects of the present disclosure. In one or more embodiments, the semiconductor package 200 may include a wide band gap semiconductor package with one or more dies in a stacked configuration. In some embodiments, the semiconductor package 200 may be produced or manufactured using advanced semiconductor packaging techniques as disclosed herein.

As illustrated in FIG. 2, the semiconductor package 200 includes a lead frame substrate 210 and a first die 220 attached to a first side of the lead-frame substrate 210 via a first layer of a coefficient of thermal expansion (CTE)-matched copper paste 225 at a first location 212 on the first side of the lead-frame substrate 210, as shown in FIG. 2. In one or more embodiments, the CTE of the CTE-matched copper paste 225 matches a CTE of the first die 220.

As further illustrated in FIG. 2, the semiconductor package 200 further includes a first set of copper clips 230 attached to the first die 220 and a second location 214 on the first side of the lead-frame substrate 210 via a second layer of CTE-matched copper paste 235. In one or more embodiments, each copper clip of the first set of copper clips 230 includes a proximal end and a distal end, wherein the proximal end is attached to the first die 220 and the distal end is attached to the second location 214 on the first side of the lead-frame substrate 210. In one or more embodiments, the attachment of the proximal end to the first die 220 occurs via the second layer of CTE-matched copper paste 235. In one or more embodiments, the attachment of the distal end to the second location 214 of the lead-frame substrate 210 occurs via the second layer of CTE-matched copper paste 235, as shown in FIG. 2.

As further shown in FIG. 2, the semiconductor package 200 further includes a second die 240 attached to the first die 220 via a third layer of CTE-matched copper paste 245. In one or more embodiments, the third layer of CTE-matched copper paste 245 is a slab of CTE-matched copper paste that functions as a heat spreader. In one or more embodiments, the CTE of the CTE-matched copper paste 245 matches a CTE of the second die 240 and the CTE of the first die 220.

As further illustrated in FIG. 2, the semiconductor package 200 further includes a second set of copper clips 250 attached to the second die 240 and a third location 216 on the first side of the lead-frame substrate 210 via a fourth layer of CTE-matched copper paste 255. In one or more embodiments, each copper clip of the second set of copper clips 250 includes a proximal end and a distal end, wherein the proximal end is attached to the second die 240 and the distal end is attached to the third location 216 on the first side of the lead-frame substrate 210. In one or more embodiments, the attachment of the proximal end to the second die 240 occurs via the fourth layer of CTE-matched copper paste 255. In one or more embodiments, the attachment of the distal end to the third location 216 of the lead-frame substrate 210 occurs via the fourth layer of CTE-matched copper paste 255, as shown in FIG. 2.

In one or more embodiments, the semiconductor package 200 further includes a third die 270a disposed atop one copper clip of the first set of copper clips 230 and a wire bond 272a formed between a top surface of the third die 270a and a fourth location 218a on the first side of the lead-frame substrate 210, as shown in FIG. 2. In one or more embodiments, the semiconductor package 200 further includes a fourth die 270b disposed atop one copper clip of the first set of copper clips 230 and a (second) wire bond 272b formed between a top surface of the fourth die 270b and a fourth location 218b on the first side of the lead-frame substrate 210, as shown in FIG. 2. In one or more embodiments, the semiconductor package 200 may include any number of additional dies, wire bonds, to be placed at any additional locations on the lead-frame substrate 210. In one or more embodiments, the third die 270a and the fourth die 270b are disposed atop the first set of copper clips 230 via a fifth layer and a sixth layer of CTE-matched copper paste 275a and 275b, respectively, as shown in FIG. 2.

In one or more embodiments, the semiconductor package 200 further includes one or more drops of cured CTE-matched copper paste disposed in gap areas between copper clips of the first set of copper clips 230. In one or more embodiments, the semiconductor package 200 further includes one or more drops of cured CTE-matched copper paste disposed in gap areas between copper clips of the second set of copper clips 250.

In one or more embodiments, the semiconductor package 200 further includes a mold compound 205 that surrounds and encapsulates the lead-frame substrate 210, the first die 220, the second die 240, the first set of copper clips 230, and the second set of copper clips 250.

In one or more embodiments, the semiconductor package 200 further includes a fifth layer of CTE-matched copper paste 260 disposed atop the second die 240 and in-between the second set of copper clips 250, as shown in FIG. 2. In one or more embodiments, the fifth layer of CTE-matched copper paste 260 is a slab of CTE-matched copper paste that functions as a heat spreader. In one or more embodiments, the semiconductor package 200 further includes a gold/nickel metallization layer 290 disposed atop the mold compound 205, as shown in FIG. 2. In one or more embodiments, the semiconductor package 200 further includes a printed circuit board (PCB) 280 attached to a second side of the lead-frame substrate 210 via a solder paste 282, for example, in a ball grid array (BGA) or a land grid array (LGA).

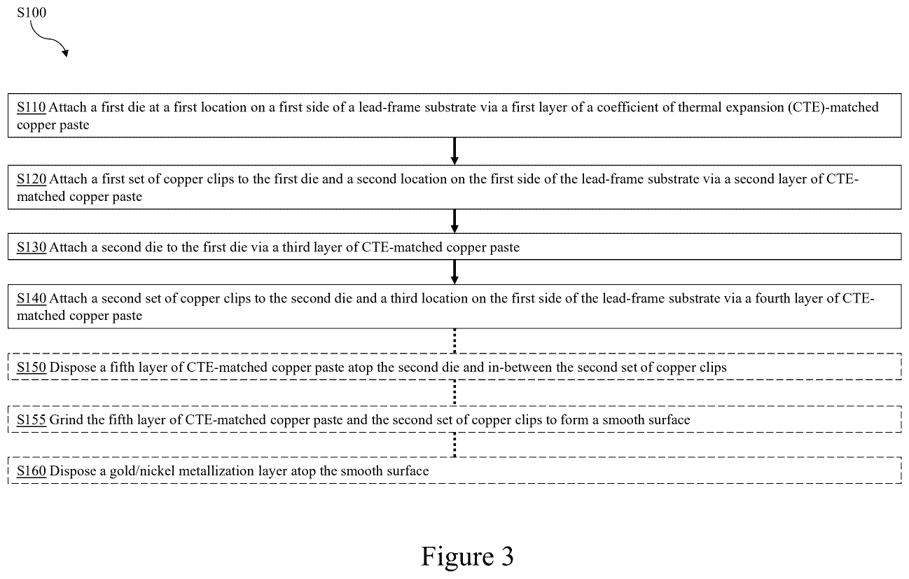

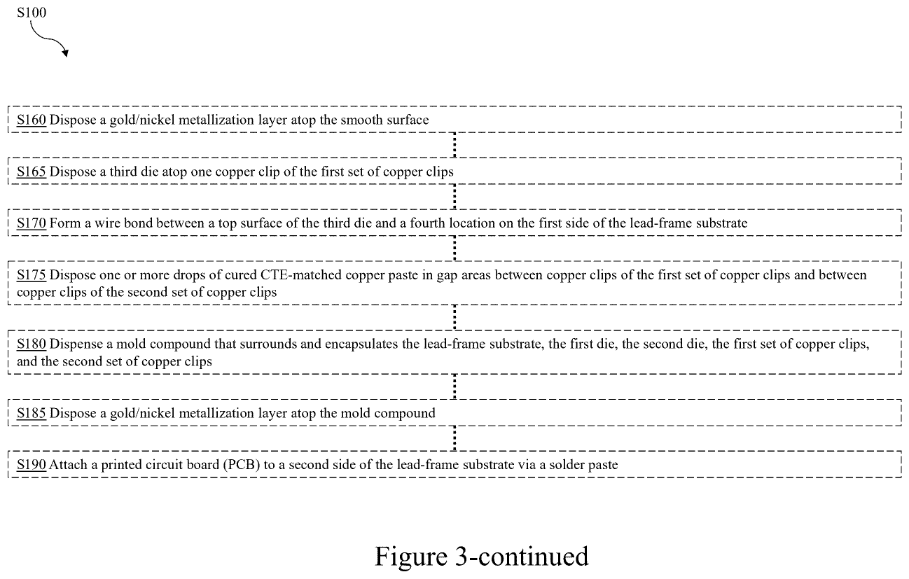

FIG. 3 illustrates a flowchart for a method S100 for forming an example semiconductor package, according to aspects of the present disclosure. In one or more embodiments, the example semiconductor package, such as semiconductor packages 100 or 200, may be produced in accordance with the method S100 disclosed herein. In one or more embodiments, a wireless device may include the semiconductor package, such as semiconductor packages 100 or 200, produced using the method S100 described herein.

As shown in FIG. 3, the method S100 includes, at step S110, attaching a first die at a first location on a first side of a lead-frame substrate via a first layer of a coefficient of thermal expansion (CTE)-matched copper paste; at step S120, attaching a first set of copper clips to the first die and a second location on the first side of the lead-frame substrate via a second layer of CTE-matched copper paste; at step S130, attaching a second die to the first die via a third layer of CTE-matched copper paste; and at step S140, attaching a second set of copper clips to the second die and a third location on the first side of the lead-frame substrate via a fourth layer of CTE-matched copper paste.

In one or more embodiments, the method S100 may further optionally include, at step S150, disposing a fifth layer of CTE-matched copper paste atop the second die and in-between the second set of copper clips; at step S155, grinding the fifth layer of CTE-matched copper paste and the second set of copper clips to form a smooth surface; and at step S160, disposing a gold/nickel metallization layer atop the smooth surface.

In one or more embodiments of the method S100, the fifth layer of CTE-matched copper paste is a slab of CTE-matched copper paste that functions as a heat spreader. In one or more embodiments, the third layer of CTE-matched copper paste is a slab of CTE-matched copper paste that functions as a heat spreader.

In one or more embodiments, the method S100 may further optionally include, at step S165, disposing a third die atop one copper clip of the first set of copper clips; and at step S170, forming a wire bond between a top surface of the third die and a fourth location on the first side of the lead-frame substrate.

In one or more embodiments, the method S100 may further optionally include, at step S175, disposing one or more drops of cured CTE-matched copper paste in gap areas between copper clips of the first set of copper clips and between copper clips of the second set of copper clips.

In one or more embodiments, the method S100 may further optionally include, at step S180, dispensing a mold compound that surrounds and encapsulates the lead-frame substrate, the first die, the second die, the first set of copper clips, and the second set of copper clips.

In one or more embodiments of the method S100, the lead-frame substrate may include the lead-frame substrates 110 or 210, the first die may include the first dies 120 or 220, the first set of copper clips may include the first set of copper clips 130 or 230, the second die may include the second dies 140 or 240, the second set of copper clips may include the second set of copper clips 150 or 250, the third die may include the third die 270a, the fourth die may include the fourth die 270b, the first layer, the second layer, the third layer, or the fourth layer of CTE-matched copper paste may include the first layers 125 or 225, the second layers 135 or 235, the third layers 145 or 245, or the fourth layers 155 or 255, the fifth layer or the sixth layer of CTE-matched copper paste may include the fifth layer 275a or the sixth layer 275b, respectively, as described with respect to FIGS. 1 and 2.

In one or more embodiments, the method S100 may further optionally include, at step S185, disposing a gold/nickel metallization layer atop the mold compound. In one or more embodiments, the method S100 may further optionally include, at step S190, attaching a printed circuit board (PCB) to a second side of the lead-frame substrate via a solder paste. In one or more embodiments, a wireless device may include the semiconductor package produced via the method as disclosed herein.

In one or more embodiments, the method S100 may include a process that begins by attaching the first die to a lead-frame substrate using CTE-matched engineered copper paste. Next, the CTE-matched copper paste is applied to the die's top edge, followed by the placement of copper clip cutouts. The assembly then undergoes thermal curing. Since the copper clip cannot cover the entire active area of the die, additional CTE-matched copper paste is printed between the copper clips to act as a heat spreader and enhance thermal performance. The minimal CTE difference between the die and the copper paste also improves the thermal and power cycling reliability of the module.

In one or more embodiments, the method S100 may include one or more steps, where a second die can be stacked onto the heat spreader of the first die using more CTE-matched copper paste. A second cut-out copper clip is then attached to the top of the second die with the same copper paste. In a similar manner, additional copper paste is printed between the second copper clip and cured. The entire assembly is then subjected to compression molding and curing using a high-voltage epoxy mold compound. Afterward, the module is co-ground to expose the top of the copper clip and CTE-matched copper heat spreader, followed by a surface finish to ensure compatibility with the next-level heat sink attachment.

In one or more embodiments, the method S100 may include one or more steps, where the module is ready for attachment to the PCB and heat sink, enabling both top-side and bottom-side cooling. This innovative assembly method significantly enhances the stacking capability of dies and copper clips in high-power modules, improving heat-spreading performance through dual-side cooling technology.

In one or more embodiments of the method S100, an additional die can be attached to the copper clip using CTE-matched copper paste and connected to the gate and source via wire bonds. This novel technique enables the integration of multiple high-power and low/medium-power dies using copper clips, significantly enhancing thermal performance.

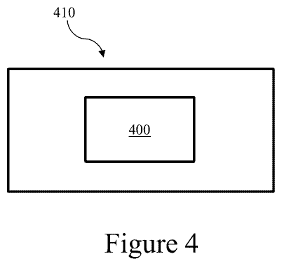

FIG. 4 illustrates an electronic device or a wireless device 410 comprising a semiconductor package 400, according to aspects of the present disclosure. In some implementations, the electronic device or wireless device 410 may include, for example, but not limited to, a computer, a cellular device, a satellite communication device, a wi-fi device, a radar, a global position system device, or any electronic device. In one or more embodiments, the semiconductor package 400 may be produced in accordance with the method S100 and/or any of the semiconductor packages 100 and 200 as described above with respect to FIGS. 1 and 2, respectively. The semiconductor package 400 may implement any radio frequency (RF) circuitry used in wireless applications, as an example, such as one or more RF power amplifiers; and the semiconductor package 400 may be coupled to other circuitry for implementing a wireless application, such as a baseband processor or other types of processors.

In one or more embodiments, the semiconductor package 400 includes a lead-frame substrate; a first die attached to a first side of the lead-frame substrate via a first layer of a coefficient of thermal expansion (CTE)-matched copper paste at a first location on the first side of the lead-frame substrate; a first set of copper clips attached to the first die and a second location on the first side of the lead-frame substrate via a second layer of CTE-matched copper paste; a second die attached to the first die via a third layer of CTE-matched copper paste; and a second set of copper clips attached to the second die and a third location on the first side of the lead-frame substrate via a fourth layer of CTE-matched copper paste.

In one or more embodiments, the semiconductor package 400 further includes a fifth layer of CTE-matched copper paste disposed atop the second die and in-between the second set of copper clips, wherein the fifth layer of CTE-matched copper paste and the second set of copper clips are ground to form a smooth surface; and a gold/nickel metallization layer disposed atop the smooth surface. In one or more embodiments, the fifth layer of CTE-matched copper paste is a slab of CTE-matched copper paste that functions as a heat spreader. In one or more embodiments, the third layer of CTE-matched copper paste is a slab of CTE-matched copper paste that functions as a heat spreader.

In one or more embodiments, the semiconductor package 400 further includes a third die disposed atop one copper clip of the first set of copper clips; and a wire bond formed between a top surface of the third die and a fourth location on the first side of the lead-frame substrate.

In one or more embodiments, the semiconductor package 400 further includes one or more drops of cured CTE-matched copper paste disposed in gap areas between copper clips of the first set of copper clips and between copper clips of the second set of copper clips.

In one or more embodiments, the semiconductor package 400 further includes a mold compound that surrounds and encapsulates the lead-frame substrate, the first die, the second die, the first set of copper clips, and the second set of copper clips.

In one or more embodiments, the semiconductor package 400 further includes a gold/nickel metallization layer disposed atop the mold compound. In one or more embodiments, the semiconductor package further includes a printed circuit board (PCB) attached to a second side of the lead-frame substrate via a solder paste. In one or more embodiments, the wireless device 410 includes the semiconductor package 400 as disclosed herein.

Persons skilled in the art will recognize that the apparatus, systems, and methods described above can be modified in various ways. Accordingly, persons of ordinary skill in the art will appreciate that the embodiments encompassed by the present disclosure are not limited to the particular exemplary embodiments described above. In that regard, although illustrative embodiments have been shown and described, a wide range of modification, change, and substitution is contemplated in the foregoing disclosure. It is understood that such variations may be made to the foregoing without departing from the scope of the present disclosure. Accordingly, it is appropriate that the appended claims be construed broadly and in a manner consistent with the present disclosure.

1. A semiconductor package, comprising:
a lead-frame substrate;
a first die attached to a first side of the lead-frame substrate via a first layer of a coefficient of thermal expansion (CTE)-matched copper paste at a first location on the first side of the lead-frame substrate;
a first set of copper clips attached to the first die and a second location on the first side of the lead-frame substrate via a second layer of CTE-matched copper paste;
a second die attached to the first die via a third layer of CTE-matched copper paste; and
a second set of copper clips attached to the second die and a third location on the first side of the lead-frame substrate via a fourth layer of CTE-matched copper paste.

2. The semiconductor package of claim 1, further comprising:
a fifth layer of CTE-matched copper paste disposed atop the second die and in-between the second set of copper clips, wherein the fifth layer of CTE-matched copper paste and the second set of copper clips are ground to form a smooth surface; and
a gold/nickel metallization layer disposed atop the smooth surface.

3. The semiconductor package of claim 2, where the fifth layer of CTE-matched copper paste is a slab of CTE-matched copper paste that functions as a heat spreader.

4. The semiconductor package of claim 1, where the third layer of CTE-matched copper paste is a slab of CTE-matched copper paste that functions as a heat spreader.

5. The semiconductor package of claim 1, further comprising:
a third die disposed atop one copper clip of the first set of copper clips; and
a wire bond formed between a top surface of the third die and a fourth location on the first side of the lead-frame substrate.

6. The semiconductor package of claim 1, further comprising:
one or more drops of cured CTE-matched copper paste disposed in gap areas between copper clips of the first set of copper clips and between copper clips of the second set of copper clips.

7. The semiconductor package of claim 1, further comprising:
a mold compound that surrounds and encapsulates the lead-frame substrate, the first die, the second die, the first set of copper clips, and the second set of copper clips.

8. The semiconductor package of claim 7, further comprising:
a gold/nickel metallization layer disposed atop the mold compound.

9. The semiconductor package of claim 1, further comprising:
a printed circuit board (PCB) attached to a second side of the lead-frame substrate via a solder paste.

10. A wireless device comprising the semiconductor package of claim 1.

11. A method for forming a semiconductor package, comprising:
attaching a first die at a first location on a first side of a lead-frame substrate via a first layer of a coefficient of thermal expansion (CTE)-matched copper paste;
attaching a first set of copper clips to the first die and a second location on the first side of the lead-frame substrate via a second layer of CTE-matched copper paste;
attaching a second die to the first die via a third layer of CTE-matched copper paste; and
attaching a second set of copper clips to the second die and a third location on the first side of the lead-frame substrate via a fourth layer of CTE-matched copper paste.

12. The method of claim 11, further comprising:
disposing a fifth layer of CTE-matched copper paste atop the second die and in-between the second set of copper clips;
grinding the fifth layer of CTE-matched copper paste and the second set of copper clips to form a smooth surface; and
disposing a gold/nickel metallization layer atop the smooth surface.

13. The method of claim 12, where the fifth layer of CTE-matched copper paste is a slab of CTE-matched copper paste that functions as a heat spreader.

14. The method of claim 11, where the third layer of CTE-matched copper paste is a slab of CTE-matched copper paste that functions as a heat spreader.

15. The method of claim 11, further comprising:
disposing a third die atop one copper clip of the first set of copper clips; and
forming a wire bond between a top surface of the third die and a fourth location on the first side of the lead-frame substrate.

16. The method of claim 11, further comprising:
disposing one or more drops of cured CTE-matched copper paste in gap areas between copper clips of the first set of copper clips and between copper clips of the second set of copper clips.

17. The method of claim 11, further comprising:
dispensing a mold compound that surrounds and encapsulates the lead-frame substrate, the first die, the second die, the first set of copper clips, and the second set of copper clips.

18. The method of claim 17, further comprising:
disposing a gold/nickel metallization layer atop the mold compound.

19. The method of claim 11, further comprising:
attaching a printed circuit board (PCB) to a second side of the lead-frame substrate via a solder paste.

20. A semiconductor package produced via the method of claim 11.

21. A wireless device comprisinga semiconductor package, the semiconductor package comprising:
a lead-frame substrate;
a first die attached to a first side of the lead-frame substrate via a first layer of a coefficient of thermal expansion (CTE)-matched copper paste at a first location on the first side of the lead-frame substrate;
a first set of copper clips attached to the first die and a second location on the first side of the lead-frame substrate via a second layer of CTE-matched copper paste;
a second die attached to the first die via a third layer of CTE-matched copper paste; and
a second set of copper clips attached to the second die and a third location on the first side of the lead-frame substrate via a fourth layer of CTE-matched copper paste.
